(19) United States
(12) Patent Application Publication
(10) Pub. No.: US 2010/0301921 A1
(43) Pub. Date: Dec. 2, 2010

(54) SWITCHING CONTROL CIRCUIT

(75) Inventors: Ryoichi Isohata, Oita-ken (JP); Junichi Todaka, Oita-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/782,166

(22) Filed: May 18, 2010

(30) Foreign Application Priority Data
May 29, 2009 (JP) 2009-130231

(51) Int. Cl. H03K 17/687; H03K 17/00

(52) U.S. Cl. 327/427; 327/365

(57) ABSTRACT

According to one embodiment, a switching control circuit includes an output circuit, a first circuit, and a second circuit. The output circuit includes an input terminal, an output terminal, and a switching element. The first circuit is connected to a control terminal of the switching element. The first circuit controls an input signal during a period when an output signal of the output circuit changes. The second circuit is connected to a control terminal of the first circuit. The second circuit generates a control signal for controlling a current flowing in the first circuit during the period when the output signal of the output circuit changes.

### CROSS-REFERENCE TO RELATED APPLICATIONS

This application is based upon and claims the benefit of priority from the prior Japanese Patent Application No. 2009-130231, filed on May 29, 2009; the entire contents of which are incorporated herein by reference.

### FIELD

Embodiments described herein relate generally to a switching control circuit for reducing switching noise in an output circuit.

### BACKGROUND

An LSI (large scale integrated circuit) includes an input/output (I/O) circuit operating as an external interface. The input/output circuit is typically based on CMOS, and performs input/output of signals by turn-on/off of the CMOS circuit.

Typically, a semiconductor device includes a plurality of output pins, and a plurality of CMOS circuits are formed therein as output circuits. When more than one of the CMOS circuits are simultaneously switched, the value of the current flowing in the power supply interconnection and ground interconnection greatly changes in a short period of time, causing variation in the potential of the power supply interconnection and ground interconnection. This noise is generally called simultaneous switching noise. The simultaneous switching noise affects the waveform and delay of the output signal, and may cause malfunctions and the decrease of operating speed.

For instance, JP-A-2003-529305 discloses a configuration in which a plurality of CMOS circuits are multi-stage connected. In the multi-stage connection of a plurality of CMOS circuits, the transistors can be turned on in a phased manner by taking advantage of the parasitic resistance and parasitic capacitance of the gate interconnection. This temporally distributes the current flowing in all the transistors to decrease the time-varying component of the current flowing in the power supply interconnection and ground interconnection. The simultaneous switching noise is suppressed.

### BRIEF DESCRIPTION OF THE DRAWINGS

FIG. 1 is a schematic configurational diagram of a switching control circuit according to this embodiment;

FIG. 2A is a circuit diagram of the switching control circuit according to the embodiment, and FIG. 2B is an operation timing chart of a relevant part of the circuit;

FIG. 3 is a circuit diagram showing one example of an output circuit; and

FIG. 4 is a circuit diagram of a switching control circuit according to another embodiment.

### DETAILED DESCRIPTION

According to one embodiment, a switching control circuit includes an output circuit, a first circuit, and a second circuit. The output circuit includes an input terminal, an output terminal, and a switching element. The first circuit is connected to a control terminal of the switching element. The first circuit controls an input signal during a period when an output signal of the output circuit changes. The second circuit is connected to a control terminal of the first circuit. The second circuit generates a control signal for controlling a current flowing in the first circuit during the period when the output signal of the output circuit changes.

Typically, an output circuit has a predefined transistor size to ensure the minimum output current in accordance with the specification of load drive capacity. Hence, the noise reduction effect reaches its limit in the connection configuration of maximizing the amount of CR delay due to the parasitic resistance and parasitic capacitance of the gate interconnection. Therefore, it is difficult to achieve further noise reduction. Furthermore, when the operating power supply voltage is low (at reduced voltage), the propagation delay time becomes longer.

Embodiments will now be described with reference to the drawings.

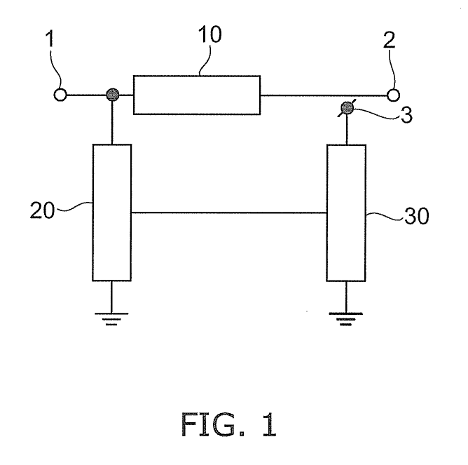

FIG. 1 shows a schematic configuration of a switching control circuit according to this embodiment.

This switching control circuit includes an output circuit 10, a first circuit 20, and a second circuit 30. The first circuit 20 is connected between an input terminal 1 of the output circuit 10 and the ground potential (ground). The second circuit 30 is connected between a power supply line 3 supplied with a power supply voltage Vcc and the ground potential (ground). The second circuit 30 generates a control signal for controlling the current flowing in the first circuit 20 and supplies the control signal to a control terminal of the first circuit 20.

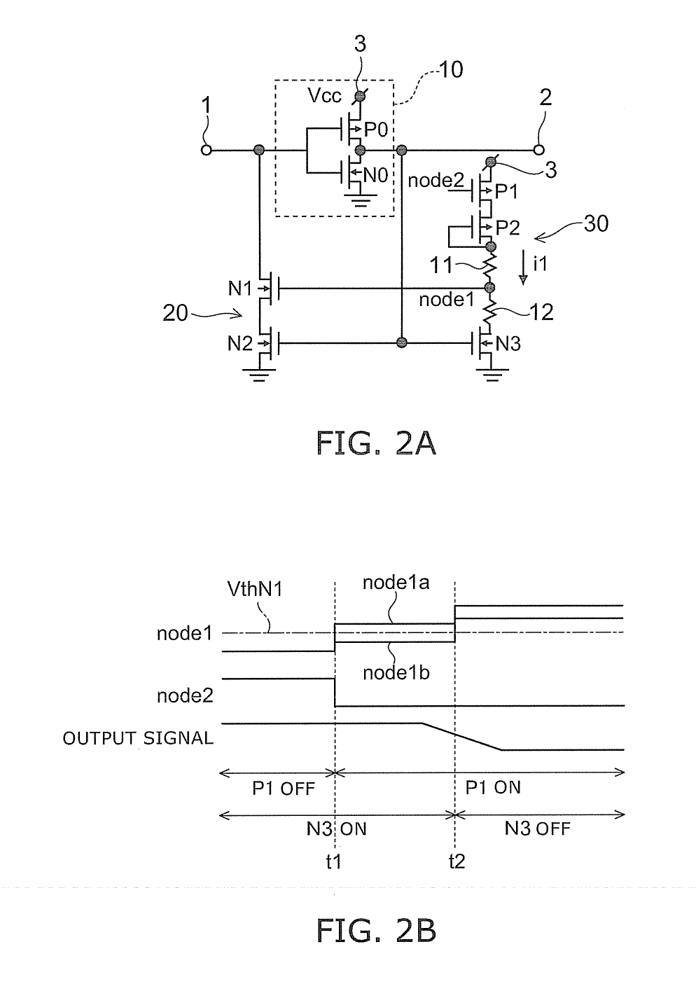

FIG. 2A is a circuit diagram showing a specific configuration example of the circuit shown in FIG. 1.

The output circuit 10 includes a CMOS circuit composed of a P-type field effect transistor P0 and an N-type field effect transistor N0 serving as switching elements. Gates, or control terminals, of the P-type field effect transistor P0 and the N-type field effect transistor N0 are connected to the input terminal 1. That is, the gates of the P-type field effect transistor P0 and the N-type field effect transistor N0 function as the input terminal of the output circuit 10.

A source of the P-type field effect transistor P0 is connected to the power supply line 3, and a source of the N-type field effect transistor N0 is connected to the ground. A drain of the P-type field effect transistor P0 is connected to a drain of the N-type field effect transistor N0. The drain of the P-type field effect transistor P0 and the drain of the N-type field effect transistor N0 are connected to an output terminal 2.

The first circuit 20 includes two N-type field effect transistors N1 and N2. A drain of the N-type field effect transistor N1 is connected to both gates (input terminal 1) of the P-type field effect transistor P0 and the N-type field effect transistor N0 in the output circuit 10. A source of the N-type field effect transistor N1 is connected to a drain of the N-type field effect transistor N2. A source of the N-type field effect transistor N2 is connected to the ground. A gate of the N-type field effect transistor N2 is connected to the output terminal 2.

The second circuit 30 includes a P-type field effect transistor P1, a P-type field effect transistor P2, a first resistor 11, a second resistor 12, and an N-type field effect transistor N3.

A source of the P-type field effect transistor P1 is connected to the power supply line 3. A drain of the P-type field effect transistor P1 is connected to a source of the P-type field effect transistor P2. A gate of the P-type field effect transistor P1 is denoted by node2, which is supplied with a signal in phase with the output signal (the signal appearing at the output terminal 2). This signal is generated illustratively by an internal logic in the preceding stage of the input terminal 1.

A drain and a gate of the P-type field effect transistor P2 are connected to each other. That is, the P-type field effect transistor P2 is diode-connected between the P-type field effect transistor P1 and the first resistor 11.

One end of the first resistor 11 is connected to the drain and gate of the P-type field effect transistor P2. The other end of the first resistor 11 is connected to one end of the second resistor 12. A connection node, node1, of the first resistor 11 and the second resistor 12 is connected to a gate of the N-type field effect transistor N1 in the first circuit 20.

The other end of the second resistor 12 is connected to a drain of the N-type field effect transistor N3. A source of the N-type field effect transistor N3 is connected to the ground. A gate of the N-type field effect transistor N3 is connected to the output terminal 2.

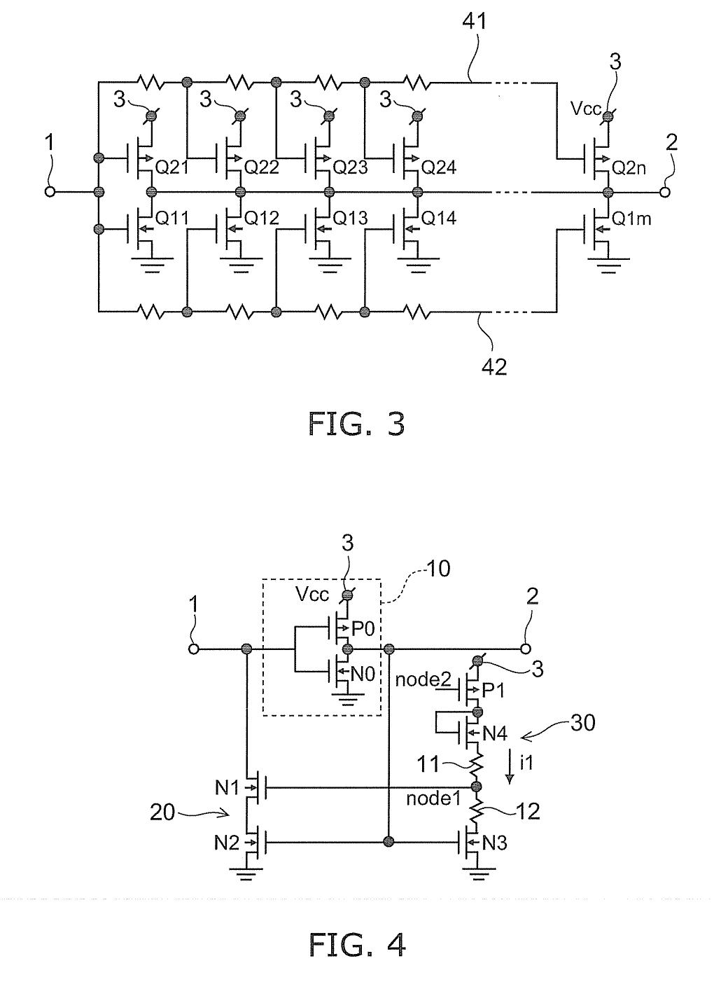

Alternatively, the output circuit 10 may be configured as shown in FIG. 3. The circuit shown in FIG. 3 includes a plurality of P-type field effect transistors Q2n (where the index n is a natural number) and a plurality of N-type field effect transistors Q1m (where the index m is a natural number). The P-type field effect transistor Q2n and the N-type field effect transistor Q1m with equal indices n and m constitute one CMOS circuit in which drains thereof are connected to each other. The drain of each P-type field effect transistor Q2n and the drain of each N-type field effect transistor Q1m are connected to the output terminal 2. That is, an output terminal of each CMOS circuit is connected to the output terminal 2.

A source of each P-type field effect transistor Q2n is connected to the power supply line 3. A source of each N-type field effect transistor Q1m is connected to the ground.

A gate of each P-type field effect transistor Q2n is connected to a gate interconnection 41. A gate of each N-type field effect transistor Q1m is connected to a gate interconnection 42. The gate interconnection 41 and the gate interconnection 42 are connected to the input terminal 1.

The gate interconnections 41, 42 have parasitic resistance and parasitic capacitance. Hence, the field effect transistors are turned on in a phased manner. This temporally distributes the current flowing simultaneously in a plurality of field effect transistors to decrease the time-varying component of the current, which can suppress simultaneous switching noise.

A logic signal at high level or low level is inputted to the input terminal 1. A logic signal at high level or low level is outputted at the output terminal 2. When a high level is inputted to the input terminal 1, the P-type field effect transistor P0 in the output circuit 10 is turned off, and the N-type field effect transistor N0 is turned on. Hence, the output terminal 2 is placed at the ground potential, or low level. When a low level is inputted to the input terminal 1, the P-type field effect transistor P0 is turned on, and the N-type field effect transistor N0 is turned off. Hence, the output terminal 2 is placed at the power supply voltage Vcc, or high level.

In the output circuit of FIG. 3, when a high level is inputted to the input terminal 1, the P-type field effect transistors Q2n are turned off, and the N-type field effect transistors Q1m are turned on sequentially from one nearest to the input terminal 1. Hence, the output terminal 2 is placed at the ground potential, or low level. When a low level is inputted to the input terminal 1, the N-type field effect transistors Q1m are turned off, and the P-type field effect transistors Q2n are turned on sequentially from one nearest to the input terminal 1. Hence, the output terminal 2 is placed at the power supply voltage Vcc, or high level.

Next, the operation of the first circuit 20 and the second circuit 30 in the circuit of FIG. 2A is described with reference to the operation timing chart of FIG. 2B.

It is assumed that at time t1, the input signal applied to the input terminal 1 is switched from low level to high level. Because the inverted signal of the input signal is applied to the node2, the potential of the node2 is switched at time t1 from high level to low level.

When the potential of the node2 is placed at low level, the P-type field effect transistor P1 is turned on. Even if the input signal is switched from low level to high level, the output signal is not immediately switched from high level to low level, but still remains at high level at time t. Hence, the gate of the N-type field effect transistor N3 is placed at high level, and the N-type field effect transistor N3 is turned on.

By turn-on of the P-type field effect transistor P1 and the N-type field effect transistor N3, the current flows from the power supply line 3 to the ground through the P-type field effect transistor P1, the P-type field effect transistor P2, the first resistor 11, the second resistor 12, and the N-type field effect transistor N3. That is, the current flows from the power supply line 3 to the ground through the second circuit 30. This establishes the potential of the node1. Hence, the gate potential of the N-type field effect transistor N1 in the first circuit 20 is established.

The dot-dashed line in the chart showing the potential variation at the node1 in FIG. 2B indicates the threshold voltage VthN1 at which the N-type field effect transistor N1 is turned on. Furthermore, node1a indicates potential variation at the node1 when the power supply voltage Vcc is relatively high, and node1b indicates potential variation at node1 when the power supply voltage Vcc is relatively low.

When the power supply voltage Vcc is relatively high, the potential of the node' exceeds the threshold voltage VthN1 of the N-type field effect transistor N1 at time t1. Thus, the N-type field effect transistor N1 is turned on. At this time, the gate of the N-type field effect transistor N2 connected to the output terminal 2 is at high level, and the N-type field effect transistor N2 is turned on.

Hence, the N-type field effect transistor N1 and the N-type field effect transistor N2 are in the on-state, and the current flows from the input terminal 1 to the ground through these N-type field effect transistor N1 and N-type field effect transistor N2. Thus, the potential of the input terminal 1 decreases, and the output circuit 10 can be gradually switched independent of the amount of CR delay of the gate interconnection. That is, simultaneous switching noise can be suppressed by temporally distributing the current flowing in the CMOS circuit constituting the output circuit 10 to decrease the time-varying component of the current.

At time t2 when the output signal (the potential of the output terminal 2) is being switched from high level to low level, the N-type field effect transistor N3 is turned off. By turn-off of the N-type field effect transistor N3, the potential of the node1 further increases at time t2. At the steady time of the output signal at low level, the N-type field effect transistor N3 is off, and no current flows in the second circuit 30. At the steady time of the output signal at high level, the P-type field effect transistor P1 is off, and no current flows in the second circuit 30.

Hence, at the steady time when the output signal does not change, no current flows in the second circuit 30, and no unwanted current is consumed. That is, only during the transient period when the output signal changes, the second circuit 30 is operated to pass a current in the first circuit 20 and decrease the potential of the input terminal 1. Thus, the simultaneous switching noise is suppressed.

Furthermore, the diode-connected P-type field effect transistor P2 provided in the second circuit 30 serves to establish the potential of the node1 in accordance with the power supply voltage Vcc. At reduced voltage with the power supply voltage Vcc being relatively low, the gate-source voltage Vgs of the P-type field effect transistor P2 increases, and the potential of the node1 decreases. That is, as indicated by the node1b in FIG. 2B, at reduced voltage, at time t1, the potential of the node1 is lower than the threshold voltage VthN1 of the N-type field effect transistor N1.

Hence, the N-type field effect transistor N1 is off, blocking the current path between the input terminal 1 and the ground. Thus, at reduced voltage, potential decrease at the input terminal 1 is suppressed, and decrease in the switching rate of the output circuit 10 is suppressed. That is, slowing down of the propagation delay time can be suppressed.

It is noted that at reduced voltage, at time t1, potential decrease at the input terminal 1 can be suppressed also by reducing the current flowing in the N-type field effect transistor N1, rather than completely blocking the N-type field effect transistor N1.

By turn-off of the N-type field effect transistor N3 at time t2, the potential of the node1 increases and exceeds VthN1. However, at time t2, the output signal has been decreased from high level, and the N-type field effect transistor N2 with the gate connected to the output terminal 2 is turned off. Hence, the current path between the input terminal 1 and the ground is blocked even if the N-type field effect transistor N1 is turned on by potential increase at the node1.

The operational analysis of the second circuit 30 can be expressed as follows.

$$\begin{matrix}\{ Vcc - Vgs ( P 2 ) \} - Vnode 1 = i 1 \cdot R 1 & ( 1 ) \\ Vnode 1 - i 1 \cdot \frac{1}{{β}_{N 3} ( {Vgs}_{N 3} - VthN )} = i 1 \cdot R 2 & ( 2 )\end{matrix}$$

Vcc is the power supply voltage applied to the power supply line 3. Vgs(P2) is the gate-source voltage of the P-type field effect transistor P2. Vnode1 is the potential of the node1. i1 is the value of the current flowing in the first resistor 11. R1 is the resistance of the first resistor 11. Vgs_{N3} is the gate-source voltage of the N-type field effect transistor N3. VthN is the threshold voltage of the N-type field effect transistor N3. R2 is the resistance of the second resistor 12. VthP is the threshold voltage of the P-type field effect transistor P2.

β_{N3} is given by β_{N3}=μ·Cox·(W/L). μ is the carrier mobility in the N-type field effect transistor N3. Cox is the capacitance of the gate oxide film in the N-type field effect transistor N3. W is the gate width in the N-type field effect transistor N3. L is the gate length in the N-type field effect transistor N3.

The following relations are derived from the above equations (1), (2).

$$Vnode 1 = \frac{R 2 + {Ron}_{N 3}}{R 1 + R 2 + {Ron}_{N 3}} \{ Vcc - Vgs ( P 2 ) \}$$

$$Vnode 1 adjustment term \text{:} \frac{R 2 + {Ron}_{N 3}}{R 1 + R 2 + {Ron}_{N 3}}$$

$$Vcc dependent term \text{:} \{ Vcc - Vgs ( P 2 ) \} \\ [ β = μ \cdot Cox \cdot \frac{W}{L} , Vgs ( P 2 ) = VthP + \sqrt{\frac{2 i 1}{β}} , \\ {Ron}_{N 3} \text{:} on \text{-} resistance of N 3 , \\ VthN \text{:} threshold voltage of N 3 ]$$

At reduced voltage with Vcc being relatively low, Vgs of the P-type field effect transistor P2 serving as a diode function element increases, and the potential of the node1 decreases. Thus, as described above, the current flowing between the input terminal 1 and the ground is blocked or decreased. Thus, decrease in the switching rate of the output circuit 10 is suppressed.

Furthermore, if the resistance R1 of the first resistor 11 is decreased by the Vnode1 adjustment term, the current flowing between the input terminal 1 and the ground increases, and the potential of the input terminal 1 is decreased. Hence, the output circuit 10 can be gradually switched independent of the amount of CR delay of the gate interconnection. That is, simultaneous switching noise can be suppressed by temporally distributing the current flowing in the CMOS circuit constituting the output circuit 10 to decrease the time-varying component of the current.

As described above, according to this embodiment, simultaneous switching noise can be reduced irrespective of the limit of the noise reduction effect dependent on the amount of CR delay. Furthermore, slowing down of the propagation delay time can be suppressed at reduced voltage with the operating power supply voltage being low. The circuit of this embodiment can be illustratively provided as a simultaneous switching noise reduction circuit in an interface between substrates, or a bus interface for signals with gradual slope.

It is noted that the P-type field effect transistor P2 in FIG. 2A may be replaced by an N-type field effect transistor N4 as shown in FIG. 4.

A drain and a gate of the N-type field effect transistor N4 are connected to each other and connected to the drain of the P-type field effect transistor P1. A source of the N-type field effect transistor N4 is connected to the first resistor 11. That is, the N-type field effect transistor N4 is diode-connected between the P-type field effect transistor P1 and the first resistor 11.

At reduced voltage, the gate-source voltage Vgs of the N-type field effect transistor N4 decreases, and the potential of the node1 decreases. Hence, the N-type field effect transistor N1 is off, blocking the current path between the input terminal 1 and the ground. Consequently, at reduced voltage, potential decrease at the input terminal 1 is suppressed, and decrease in the switching rate of the output circuit 10 is suppressed. That is, slowing down of the propagation delay time can be suppressed.

In the examples shown in FIGS. 2A and 4, the field effect transistor P2, N4 is used as a diode function element. However, the field effect transistor P2, N4 may be replaced by a diode.

The circuit described above is formed as an integrated circuit on a semiconductor substrate. By using the field effect transistor P2, N4 as a diode function element, the field effect transistor P2, N4 can also be formed in the same process as other field effect transistors which are not diode-connected. This eliminates the need of an additional process for forming diodes.

The embodiments have been described with reference to examples. However, the invention is not limited thereto, but can be variously modified within the spirit of the invention.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A switching control circuit comprising:
an output circuit including an input terminal, an output terminal, and a switching element;
a first circuit, connected to a control terminal of the switching element, controlling an input signal during a period when an output signal of the output circuit changes; and
a second circuit, connected to a control terminal of the first circuit, generating a control signal for controlling a current flowing in the first circuit during the period when the output signal of the output circuit changes.

2. The circuit according to claim 1, wherein
the first circuit includes a first field effect transistor and a second field effect transistor connected in series between the control terminal of the switching element and ground potential,
a gate of the first field effect transistor receives the control signal of the second circuit, and
a gate of the second field effect transistor is connected to the output terminal of the output circuit.

3. The circuit according to claim 1, wherein
the second circuit includes a diode function element, a first resistor, and a second resistor connected in series between a power supply voltage source and ground potential sequentially from the power supply voltage source side, and
a connection node of the first resistor and the second resistor is connected to the control terminal of the first circuit.

4. The circuit according to claim 3, wherein the diode function element is a field effect transistor diode-connected between the power supply voltage source and the first resistor.

5. The circuit according to claim 3, wherein the second circuit controls a current flowing in the first circuit in accordance with a power supply voltage of the power supply voltage source.

6. The circuit according to claim 1, wherein
the first circuit includes a first field effect transistor and a second field effect transistor connected in series between the control terminal of the switching element and ground potential,
the second circuit includes a third field effect transistor, a diode function element, a first resistor, a second resistor, and a fourth field effect transistor connected in series between a power supply voltage source and the ground potential sequentially from the power supply voltage source side,
a gate of the first field effect transistor is connected to a connection node of the first resistor and the second resistor,
a gate of the second field effect transistor and a gate of the fourth field effect transistor are connected to the output terminal of the output circuit, and the second field effect transistor and the fourth field effect transistor are turned on when the output signal is at high level, and
the third field effect transistor is turned on when the input signal is switched to place the output signal at low level.

7. The circuit according to claim 6, wherein at a steady period when the output signal does not change, one of the third field effect transistor and the fourth field effect transistor is turned off, and no current flows in the second circuit.

8. The circuit according to claim 6, wherein
a potential of the connection node of the first resistor and the second resistor is relatively high when the power supply voltage of the power supply voltage source is relatively high, and
the potential of the connection node is relatively low when the power supply voltage of the power supply voltage source is relatively low.

9. The circuit according to claim 6, wherein the third field effect transistor is turned on, the potential of the connection node exceeds a threshold for turning on the first field effect transistor, the first field effect transistor is turned on, and a current flows in the first circuit to decrease a potential of the input terminal when the input signal is switched to place the output signal at low level with the relatively-high power supply voltage.

10. The circuit according to claim 9, wherein the potential of the connection node does not reach the threshold for turning on the first field effect transistor even if the third field effect transistor and the fourth field effect transistor are turned on with the relatively-low power supply voltage.

11. The circuit according to claim 10, wherein the second field effect transistor is off when the fourth field effect transistor is turned off during switching of the output signal from high level to low level and the potential of the connection node exceeds the threshold of the first field effect transistor.

12. The circuit according to claim 6, wherein the diode function element is a field effect transistor diode-connected between the third field effect transistor and the first resistor and formed on a semiconductor substrate in a process equal to the first field effect transistor, the second field effect transistor, the third field effect transistor, and the fourth field effect transistor.
